(19) United States
(12) Patent Application Publication
(10) Pub. No.: US 2014/0307423 A1
(43) Pub. Date: Oct. 16, 2014

(54) FLEXIBLE INTERCONNECT CIRCUITRY

(71) Applicant: Oryon Technologies, LLC, Addison, TX (US)

(72) Inventor: Melvin K. Coats, Aubrey, TX (US)

(21) Appl. No.: 14/252,027

(22) Filed: Apr. 14, 2014

Related U.S. Application Data
(60) Provisional application No. 61/811,386, filed on Apr. 12, 2013.

(51) Int. Cl. H05K 1/14; F21V 33/00; F21V 21/14

(52) U.S. Cl. CPC H05K 1/147; F21V 21/14; F21V 33/0008
USPC 362/103; 174/254; 362/418

(57) ABSTRACT

A flexible electric circuit has at least two flexible electrical conductors adhered to a textile base. A connector patch is adhered to the textile base over the flexible conductors. The connector patch has a plurality of separate conductive areas at least equal to the number of flexible electrical conductors. The conductive areas are located in the connector patch so that each flexible electrical conductor is contacted by a conductive area. The connector patch is preferably made by printing layers to form a top and bottom part with aligned windows. The bottom part is printed over with a conductive ink at the location of the windows in the bottom part, thus forming conductive areas through the connector patch. A second flexible electric circuit may be placed in electrical contact with the first flexible electrical circuit by adhering the second circuit over the connector patch so that the conductors of the second circuit contact the conductive areas. The flexible electrical circuit may be attached to a garment and supply power to electroluminescent lamps attached to the garment.

### CLAIM FOR PRIORITY

This application claims the priority of U.S. Provisional Application Ser. No. 61/811,386, filed Apr. 12, 2013, which application is incorporated into the present application by reference in its entirety.

### BACKGROUND

1. Technical Field

This application relates generally to electric circuits; specifically to flexible electrical conductors and connections between such conductors where the same are incorporated into fabrics and fabric garments.

2. Background

Illuminated garments, such as vests, jackets and shirts, have been made with light-emitting diode LED or electroluminescent EL lamps. Such garments are particularly useful as safety indicators for joggers, cyclists and emergency response personnel. In some applications, it is also desirable to integrate electronic devices, such as radios or tracking beacons into clothing.

Typically, a power source, such as a battery pack, is mounted within the garment, and connected by an electric circuit to the lamp or lamps. It is important that the circuit connections be as flexible as possible so as not to interfere with a wearer's comfort or mobility. Where multiple lamps are used, this goal becomes difficult to achieve because multiple lines must be used to selectively energize different lamps. Further, mounting the circuits in the garment becomes more difficult and expensive as circuit complexity increases. The typically used plastic strips are relatively stiff compared to textiles, and they become stiffer in cold environments. Runs of single electric wires are more flexible, but must be carefully routed and held in place to prevent loosening and breakage in normal use.

What is needed is an electric circuit with flexibility approaching that of the garment cloth itself, that remains flexible even in cold weather, can be laundered, and the connectors of which can be rapidly assembled and integrated into a garment with less expense than current methods.

### DRAWINGS

FIG. 1A shows an exemplary wiring circuit. FIG. 1B shows straight connector patches. FIG. 1C shows a straight connector connecting a circuit assembly to a hard connection. FIG. 1D shows a T connector having a first and second part.

FIG. 2A shows an exploded view of an embodiment of the first part of a T-connector patch to be attached to a flexible electric circuit. FIG. 2B shows the second overlapping part of the T-connector patch.

FIG. 3 shows a view of a parallel flexible electric circuit in electric contact with a first flexible electric circuit through a T-connector.

FIG. 4 shows an exemplary flexible EL lamp assembly for connection to a flexible electric circuit.

FIG. 5 shows a plan view of a lighted garment constructed from a plurality of flexible electric circuits, EL lamps, and connector patches.

### DETAILED DESCRIPTION

The flexible interconnect circuitry system disclosed here provides an easily installable electrical circuit for the integration of electronics into fabrics and other flexible assemblies. All components of the flexible interconnect are attached to each other and to the fabric product by heat using a common apparel assembly practices. It comprises primarily two components: circuit tape which is comprised of a conductor laminated between two layers of thermal set, waterproof seam tape; and, connectors which are printed silver traces with print thermal set, silver ink on polyurethane. A suitable conductive ink is No. 124-33, manufactured by Creative Materials, Inc. of Tyngsboro, Mass. The flexible conductor is preferably a conductive yarn, such as Circuit X, manufactured by Noble Biomaterials, Inc. of Scranton, Pa., however, the flexible conductor can be anything that is electrically conductive, such as thin wire, and this is included in the meaning of “conductive fiber.” Conductive yarns have a higher electric resistance than metallic conductors, but this higher resistance is not significant given the relatively high voltages and low currents at which EL lamps work. Conductive yarns therefore provide adequate electric conductivity while also providing the flexibility of a textile.

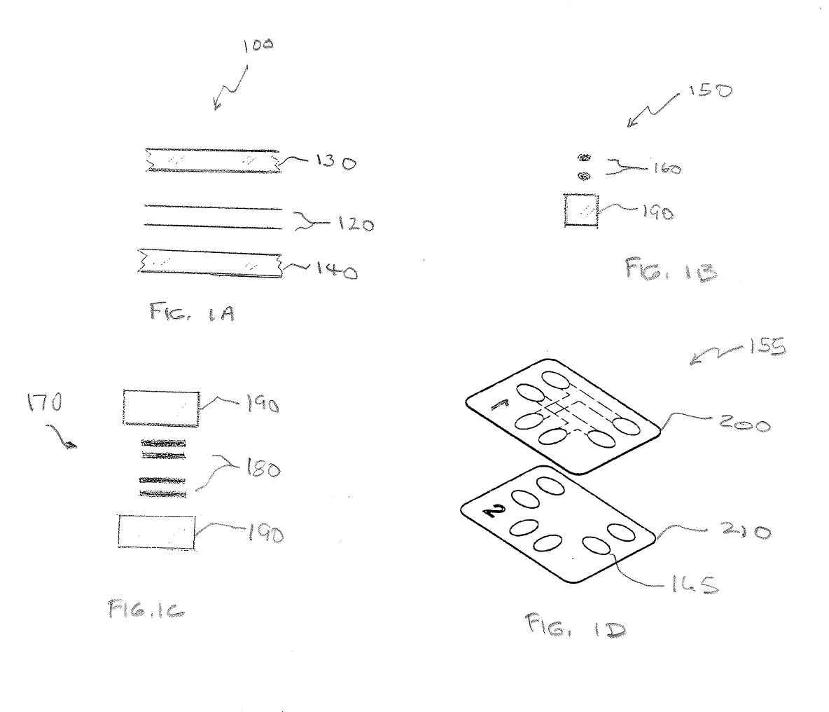

FIG. 1A shows an exemplary wiring circuit 100. The circuit tape, or “wiring circuit” 100 is made up of two or more strands of conductive fiber 120 that is placed on the adhesive side of the thermal set, waterproof seam tape 130 with a fixed spacing pitch. A second layer of thermal set, waterproof seam tape 140 is laminated to the first layer 130 with the non-adhesive side facing the adhesive side of the first seam tape 130 and with the conductive fiber pair 120 sandwiched in between. The circuit tape 100 is preferably packaged on rolled spools for ease of use in assembly.

As shown in FIG. 1B, straight connector patches 150 are printed with conductive ink in a number of configurations with two or more traces having the same fixed pitch as the conductive fibers 120 of the circuit tape 100.

The conductive patch 150 comprises printed conductive adhesive areas 160 of thermal set, conductive ink arranged so that the areas 160 line up with the conductive fiber 120 of the circuit tape covered with a printed polyurethane layer 190. The conductive areas 160 are depicted as approximately oval in the drawings, but may be any convenient shape.

As shown in FIG. 1C, a straight connector 170 is used to connect the flexible circuit assembly 100 to “hard” connections such as wires or terminals not shown, and comprises printed parallel traces 180 using conductive ink and thermal set conductive ink, preferably on polyethylene backing 190. Two straight connectors 170 are used, with the conductive traces 180 facing each other to capture the conductive fiber 120.

FIG. 1D shows a T-connector 155 having a first part 200 and a second part 210, arranged to engage conductors 120 between the two parts to form the connection. The T-connector is explained in the following.

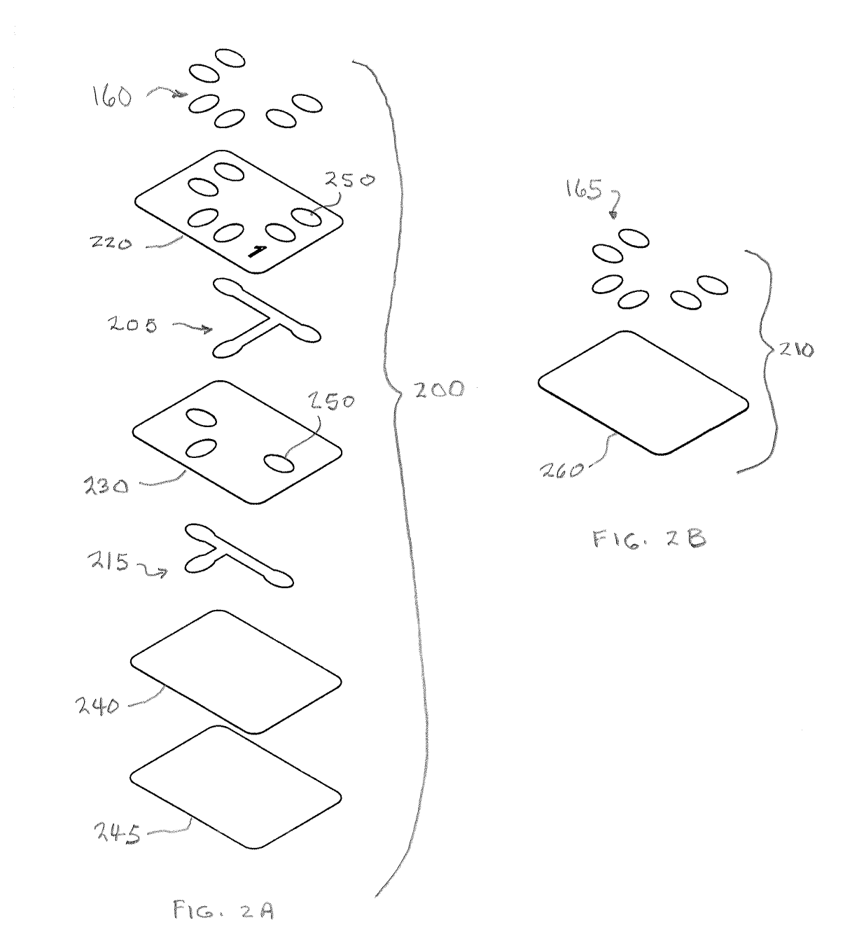

FIG. 2 shows the preferred construction of the T-connector 155 used to connect two or more circuits together. In this embodiment, the T-connector 155 comprises a first part 200, shown in FIG. 2A and a second overlapping part, 210, shown in FIG. 2B. The first part 200 and the second part 210 have overlapping “T” shaped conductive trace geometries 205, 215 offset by the same pitch as conductive fiber 120 of the circuit tape 100.

Further as shown in FIG. 2A, a first layer 160 of conductive ink is printed, followed by a layer 220 of polyurethane with vias, or windows, 250 cut to allow electrical connection to be made to the thermal set conductive ink 160. This is followed by a printed conductive trace 205, forming one contact on each leg of the T geometry. The next step is another layer 230 of polyurethane with windows 250 over the three unused contacts of the T configuration. Another layer 215 of conductive ink is then applied to connect the remaining three contacts of the T configuration. A polyurethane envelope 240 is printed next, followed by a layer of adhesive 245 printed on the envelope 240.

FIG. 2B shows the second overlapping part 210 of the T-connector. A second layer of conductive ink 165, matching the geometry of the first layer of conductive ink 160 in the first part 200, is printed on a polyurethane envelope 260. The completed T-connector 155 is assembled as shown in FIG. 1C. Conductive fibers 120 are placed on the three circuit areas 165 of the second part 210 before the first part 200 and the second part 210 are connected together. All connectors are placed on the adhesive side of the circuit tape 100 for integration into fabrics or textiles. The T connector patch 155 is preferably created by screen printing methods known in the art.

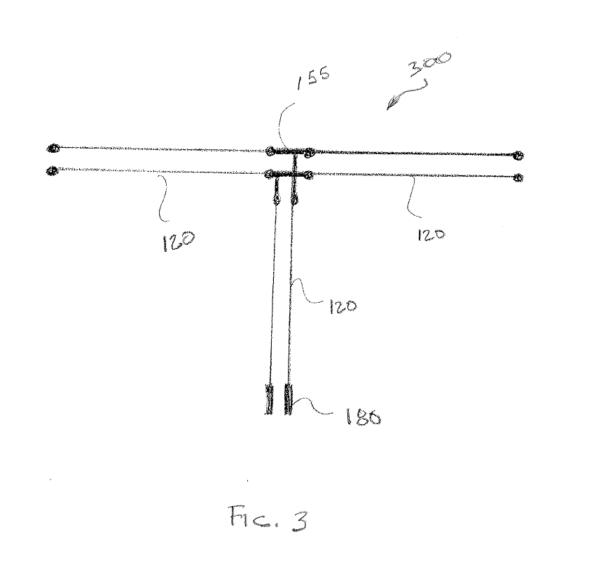

FIG. 3 is a view of a T-connected electric circuit 300. It comprises a T connector patch 155, circuit tape 100 forming the circuit, and straight connectors 170 at the ends of the conductive fibers 120 for connection to electrical power or lamps.

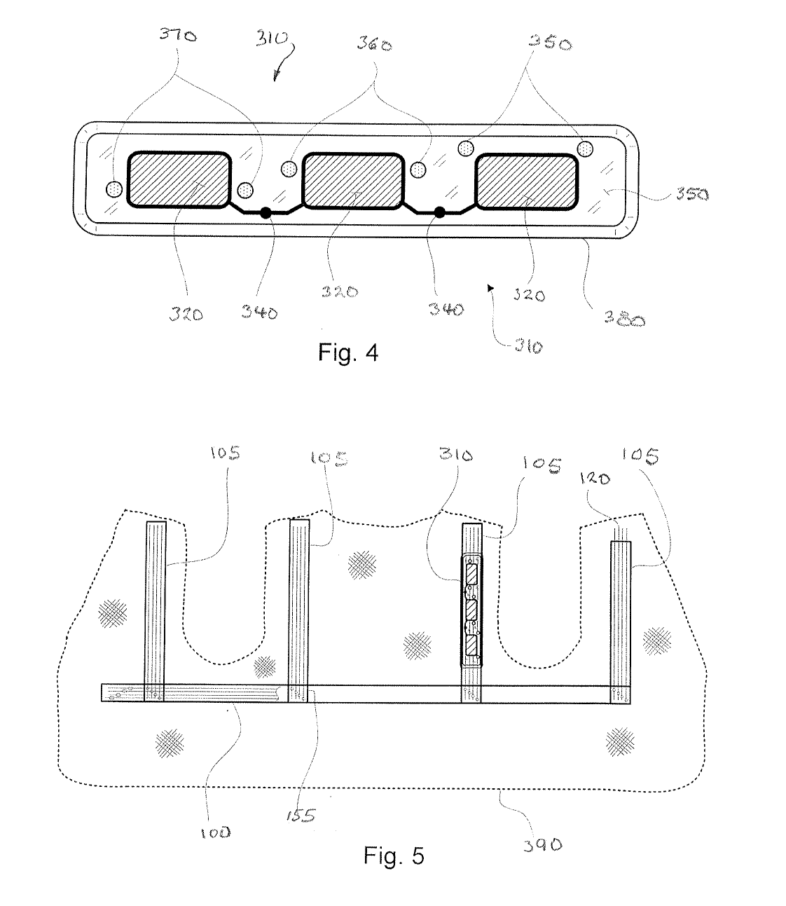

FIG. 4 shows an exemplary EL lamp assembly 310, comprising three EL lamps 320. The lamps are preferably screen-printed by methods known in the art for the production of thin, flexible EL lamps. See, for example, U.S. Pat. No. 5,856,030 to Burrows. The lamps 320 are disposed on a substrate 330 and connected by a common conductor 340. The second connections to the lamps 320 are located in pairs in this example near each lamp 320, but offset along the length of the lamp assembly 310 by a spacing equal to that of the flexible conductors 120 in a flexible circuit 100. Moving from right to left in FIG. 4, first connections 350 connect to the first lamp 320, second connections 360 to the next lamp 320, and third connections 370 to the last lamp 320. This allows each lamp 320 to be selectively energized by a separate flexible electrical conductor 120 disposed across the respective connections 350, 360, and 370.

FIG. 4 also shows the EL lamp assembly 310 laminated on a polyurethane layer 380 to add strength and wear resistance. A suitable material is No. 3415, manufactured by Bemis Company Inc., or one of its subsidiaries, of Stow, Ohio. This layer 380 is on the light-emitting side of the lamps 320, to protect them from moisture and abrasion.

FIG. 5 shows the EL lamp assembly 310 adhered to the second flexible electric circuit 105, which is electrically connected to the first flexible electric circuit 100. FIG. 5 shows four such second flexible electric circuits 105 arranged upon a fabric piece 390. The fabric piece 390 is cut to form a garment, in this case a vest. Only one EL lamp assembly 310 is shown for clarity, although at least one such assembly 310 would be attached to each of the second flexible electric circuits 105. The first flexible electric circuit 100 acts as an electric bus, providing current to the various flexible electrical conductors 120 in the flexible electric circuits 100, 105 through the connector patches 150. The T connector patches 155 together with the circuits 100, 105 form a circuit branch connection for each of the second flexible electric circuits 105. For clarity, the full length of the flexible electrical conductors 120 in the first flexible electric circuit 100 is not shown.

The flexible electric circuits 100, 105 and attached lamp assemblies 310 are affixed to the fabric piece 390 by pressure and heat to set the adhesive film bonded thereto.

The reader will see that many variations in the size and shape of the flexible electric circuits 100, their connections, and the attachment of lamps is possible. Since those skilled in the art can modify the specific embodiments described above, I intend that the claims be interpreted to cover such modifications and equivalents.

1. A flexible electric circuit, comprising:
at least two flexible electrical conductors;
a textile base;
the flexible electrical conductors adhered to the textile base;
a connector patch adhered to the textile base;
the connector patch comprising;
a plurality of separate conductive areas; the number of separate conductive areas at least equal to the number of flexible electrical conductors;
the separate conductive areas being disposed in the connector patch so that each flexible electrical conductor is contacted by a conductive area.

2. The flexible electric circuit of claim 1, where the connector patch further comprises:
top part and a bottom part;
the top part having at least two windows and the bottom part having at least two windows; the number of windows in the top part and the bottom part corresponding to at least the number of flexible electrical conductors;
the windows in the top part and the windows in the bottom part disposed substantially in alignment with one another.

3. The flexible electric circuit of claim 2, where each conductive area is located within each pair of aligned windows in the top part and the bottom part of the conductive patch, so that each conductive area forms a conductive region between the top part and the bottom part of the conductive patch.

4. The flexible electric circuit of claim 1, where the connector patch comprises a plurality of layers of a curable polyurethane ink.

5. The flexible electric circuit of claim 1, where the conductive areas comprise a plurality of layers of a thermally cured electrically conductive ink.

6. The flexible electric circuit of claim 1, further comprising a lamp electrically connected to the flexible electrical conductors.

7. The flexible electric circuit of claim 6, further where the lamp is an electroluminescent lamp.

8. The flexible electric circuit of claim 1, further comprising:
a garment;
the garment attached to the flexible electric circuit;
at least one electroluminescent lamp;
the electroluminescent lamp electrically connected to the flexible electric circuit.

9. A electrically-connected combination of flexible electric circuits, comprising:
a first flexible electric circuit; the first flexible electric circuit comprising:
at least two first flexible electrical conductors;
a first textile base;
the first flexible electrical conductors adhered to the first textile base;
a connector patch adhered to the first textile base;
the connector patch comprising;
a plurality of separate conductive areas; the number of separate conductive areas at least equal to the number of first flexible electrical conductors;
the separate conductive areas being disposed in the connector patch so that each of the first flexible electrical conductors is contacted by a conductive area; and,
a second flexible electric circuit; the second flexible electric circuit comprising:
at least two second flexible electrical conductors;
a second textile base;
the second flexible electrical conductors adhered to the second textile base;
where the second flexible electric circuit is disposed on the connector patch so that each of the second flexible electrical conductors is contacted by a conductive area.

10. The electrically-connected combination of flexible electric circuits of claim 9, where the connector patch further comprises:
top part and a bottom part;
the top part having at least two windows and the bottom part having at least two windows; the number of windows in the top part and the bottom part corresponding at least to the number of first flexible conductors;
the windows in the top part and the windows in the bottom part disposed substantially in alignment with one another.

11. The electrically-connected combination of flexible electric circuits of claim 10, where each conductive area is located within each pair of aligned windows in the top part and the bottom part of the conductive patch, so that each conductive area forms a conductive region between the top part and the bottom part of the conductive patch.

11. The electrically-connected combination of flexible electric circuits of claim 9, where the connector patch comprises a plurality of layers of a curable polyurethane ink.

13. The electrically-connected combination of flexible electric circuits of claim 9, where the conductive areas comprise a plurality of layers of a thermally cured electrically conductive ink.

14. The electrically-connected combination of flexible electric circuits of claim 9, further comprising a lamp electrically connected to one of the first or second flexible electrical circuits.

15. The electrically-connected combination of flexible electric circuits of claim 14, further where the lamp is an electroluminescent lamp.

16. The electrically-connected combination of flexible electric circuits of claim 9, further comprising:
a garment;
the garment connected to the flexible electric circuit;
at least one electroluminescent lamp;
the electroluminescent lamp electrically connected to the flexible electric circuit.
